(19) United States
(12) Patent Application Publication
(10) Pub. No.: US 2013/0133428 A1
(43) Pub. Date: May 30, 2013

(54) FINGERPRINT DETECTION SENSOR AND METHOD OF MANUFACTURING THE SAME

(71) Applicants: Seung Seoup Lee, Suwon (KR); Il Kwon Chung, Seongnam (KR); Jae Hyouck Choi, Seongnam (KR); Jun Kyung Na, Anyang (KR)

(72) Inventors: Seung Seoup Lee, Suwon (KR); Il Kwon Chung, Seongnam (KR); Jae Hyouck Choi, Seongnam (KR); Jun Kyung Na, Anyang (KR)

(73) Assignee: SAMSUNG ELECTRO-MECHANICS CO., LTD., Suwon (KR)

(21) Appl. No.: 13/401,327

(22) Filed: Feb. 21, 2012

(30) Foreign Application Priority Data
Nov. 30, 2011 (KR) 10-2011-0127166

(51) Int. Cl. G01N 29/22; H01L 41/22; G01L 1/16

(52) U.S. Cl. 73/589; 73/862.046; 29/25.35

(57) ABSTRACT

There are provided a fingerprint detection sensor and a method of manufacturing the same. The fingerprint detection sensor includes a plurality of piezoelectric sensors arranged in an array on a two-dimensional plane and having a predetermined height; a filler provided to surround the plurality of piezoelectric sensors and isolating vibrations between the plurality of piezoelectric sensors; and a control unit discharging predetermined output signals through the piezoelectric sensors to detect information of an object in contact with, or close to, the plurality of piezoelectric sensors, wherein the plurality of piezoelectric sensors include first surfaces and second surfaces disposed on both ends thereof in a height direction and areas of the first surfaces and the second surfaces are different from each other.

### CROSS-REFERENCE TO RELATED APPLICATIONS

This application claims the priority of Korean Patent Application No. 10-2011-0127166 filed on Nov. 30, 2011, in the Korean Intellectual Property Office, the disclosure of which is incorporated herein by reference.

### BACKGROUND OF THE INVENTION

1. Field of the Invention

The present invention relates to a fingerprint detection sensor and a method of manufacturing the same, capable of improving resolution in fingerprint detection by arranging a plurality of piezoelectric sensors, each having a pillar shape in an array and reducing a surface of each of the plurality of piezoelectric sensors disposed adjacent to an object.

2. Description of the Related Art

A fingerprint detection sensor, a sensor for detecting a human fingerprint, has been used in apparatuses such as an existing door lock, or the like, and has also been widely used to determine whether a power supply of an electronic device is turned on or off or whether a sleep mode thereof has been released. In particular, unlike the type of fingerprint detection sensor generally used for the door lock, a swipe type fingerprint detection sensor capable of being configured to have a small volume has recently been developed, and thus, the fingerprint detection sensor is prevalently being used in mobile devices.

Fingerprint detection sensors may be classified into an ultrasonic type, an infrared type, a capacitive type, or the like, according to an operational principle thereof. Among these, the ultrasonic type fingerprint detection sensor is a type of fingerprint detection sensor detecting a fingerprint by measuring a difference in acoustic impedance between each valley and each ridge of the fingerprint by using an ultrasonic wave generation source, that is, a plurality of corresponding piezoelectric sensors, when the ultrasonic signals of a predetermined frequency discharged from the plurality of piezoelectric sensors are reflected from the valleys and ridges of the fingerprint. In particular, the ultrasonic type fingerprint detection sensor may be advantageous in that it has a function of detecting blood streams in fingers by generating pulse-type ultrasonic waves and detecting a Doppler effect due to the reverberation of the pulse-type ultrasonic waves, in addition to a function of simply detecting a fingerprint and thus, may determine whether the fingerprint has been forged by using the function.

In the ultrasonic type fingerprint detection sensor, in order to increase the accuracy of fingerprint detection, there is a need to increase the number of piezoelectric sensors. In particular, in order to accurately detect a fingerprint of a child or a woman in which intervals between valleys and ridges thereof may be very dense, there is a need to increase the number of piezoelectric sensors disposed per a unit area, that is, resolution. However, in order to increase resolution in the plurality of piezoelectric sensors, areas of each of the piezoelectric sensors should be reduced, leading to problems in a manufacturing process, thereby degrading yield, price competitiveness, and the like.

### SUMMARY OF THE INVENTION

An aspect of the present invention provides a fingerprint detection sensor including a plurality of piezoelectric sensors, wherein areas of a first surface and a second surface facing each other in a height direction of the piezoelectric sensors are different and a surface having a smaller area is disposed to be closer to an object.

Another aspect of the present invention is provided to increase resolution by increasing the number of piezoelectric sensors disposed per unit area while the overall volume of the fingerprint detection sensor is maintained so as to be equal to that of a sensor according to the related art, thereby being able to accurately detect a fingerprint of a child or woman in which intervals between valleys and ridges thereof may be small.

According to an aspect of the present invention, there is provided a fingerprint detection sensor, including: a plurality of piezoelectric sensors arranged in an array on a two-dimensional plane and having a predetermined height; a filler provided to surround the plurality of piezoelectric sensors and isolating vibrations between the plurality of piezoelectric sensors; and a control unit discharging predetermined output signals through the piezoelectric sensors to detect information of an object in contact with, or close to, the plurality of piezoelectric sensors, wherein the plurality of piezoelectric sensors include first surfaces and second surfaces disposed on both ends thereof in a height direction and areas of the first surfaces and the second surfaces are different from each other.

The first surfaces of the plurality of piezoelectric sensors may have an area smaller than that of the second surfaces and the first surfaces are disposed to be closer to the object, as compared with the second surfaces.

The plurality of piezoelectric sensors may be arranged such that the first surfaces have a resolution of 500 dots per inch (DPI) or more on the two-dimensional plane.

The control unit may discharge ultrasonic output signals having a predetermined frequency through the plurality of piezoelectric sensors and detect fingerprint information of the object by measuring a difference in acoustic impedance generated in valleys and ridges of the object by the output signals.

The control unit may detect the fingerprint information of the object based on the difference between first acoustic impedance corresponding to the valleys of the object and second acoustic impedance corresponding to the ridges of the object.

The control unit may detect fingerprint patterns of the object.

The fingerprint detection sensor may further include a polymer filler disposed to surround the plurality of piezoelectric sensors.

The fingerprint detection sensor may further include a protective layer provided on the plurality of piezoelectric sensors.

According to another aspect of the present invention, there is provided a method of manufacturing a fingerprint detection sensor determining information of a contacting or approaching object, the method including: preparing a plurality of piezoelectric sensors, each including a first surface and a second surface facing each other in a height direction thereof and having different areas; disposing a polymer filler to surround the plurality of piezoelectric sensors; and connecting a control unit discharging predetermined output signals through the plurality of piezoelectric sensors to the plurality of piezoelectric sensors.

The area of the first surface may be smaller than that of the second surface.

The preparing of the plurality of piezoelectric sensors may be performed such that the first surface is closer to the contacting or approaching object, as compared with the second surface.

In the connecting of the control unit, the control unit determining information of the object by comparing a frequency of output signals discharged through the plurality of piezoelectric sensors with a frequency of reflection signals reflected from the object, may be connected to the plurality of piezoelectric sensors.

The preparing of the plurality of piezoelectric sensors may be performed such that the plurality of piezoelectric sensors have a resolution of 500 DPI or more on a two-dimensional plane, with which the object is in contact or approaching.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view illustrating a fingerprint detection sensor according to an embodiment of the present invention;

FIG. 2 is a block view schematically illustrating a fingerprint detection sensor according to another embodiment of the present invention;

FIGS. 3A and 3B are cross-sectional views, each illustrating a plurality of piezoelectric sensors included in the fingerprint detection sensor according to another embodiment of the present invention;

FIGS. 4 to 5 are views, each for explaining an operation principle of a fingerprint detection sensor according to another embodiment of the present invention; and

FIG. 6 is a flow chart for explaining a method of manufacturing a fingerprint detection sensor according to an embodiment of the present invention.

### DETAILED DESCRIPTION OF THE EMBODIMENTS

A detailed description of the present invention to be described below refers to the accompanying drawings shown as a predetermined embodiment that can implement the present invention as an example. The embodiments are described in detail so that those skilled in the art can implement the present invention sufficiently. It should be appreciated that various embodiments of the present invention are different from each other, but the embodiments do not need to be exclusive to each other. For example, specific shapes, configurations, and characteristics described in an embodiment of the present invention may be implemented in another embodiment without departing from the spirit and the scope of the present invention. In addition, it should be understood that position and arrangement of individual components in each disclosed embodiment may be changed without departing from the spirit and the scope of the present invention. Therefore, a detailed description described below should not be construed as being restrictive. In addition, the scope of the present invention is defined only by the accompanying claims and their equivalents if appropriate. The similar reference numerals will be used to describe the same or similar functions throughout the accompanying drawing.

Hereinafter, embodiments of the present invention will be described in detail with reference to the accompanying drawings so that those skilled in the art may easily practice the present invention.

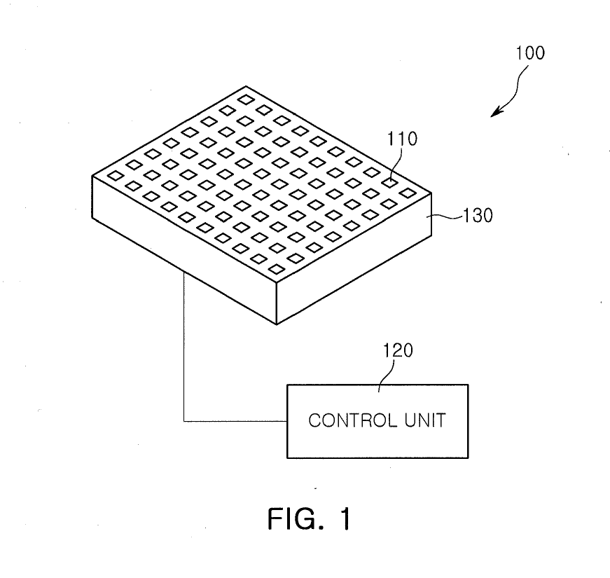

FIG. 1 is a view illustrating a fingerprint detection sensor according to an embodiment of the present invention.

Referring to FIG. 1, a fingerprint detection sensor 100 according to an embodiment of the present invention may include a plurality of piezoelectric sensors 110, a control unit 120 electrically connected with the plurality of piezoelectric sensors 110 to detect a fingerprint, and a polymer filler 130 provided to surround the plurality of piezoelectric sensors 110. The plurality of piezoelectric sensors 110 and the polymer filler 130 may be arranged to form an array in a matrix form on a two-dimensional plane.

The control unit 120 may be connected to each of the plurality of piezoelectric sensors 110, in particular, may be connected to electrodes disposed on the top and bottom of each piezoelectric sensor 10 in a height direction thereof. Each piezoelectric sensor 110 may be a 1-3 piezo composite and may be manufactured by disposing electrodes on top and bottom surfaces of a pillar extending in a height direction. The pillar may be made of at least one of PZT, PST, Quartz, (Pb, Sm)TiO₃, PMN(Pb(MgNb)O₃)-PT(PbTiO₃), PVDF, and PVDF-TrFe.

The control unit 120 may apply voltage having a resonance frequency in an ultrasonic band to the electrodes disposed on top and bottom surfaces of the pillars to vertically vibrate the pillars, thereby generating ultrasonic signals. The top and bottom surfaces of each piezoelectric sensor 110, each may be a square or circle having a side or diameter of 40 to 50 μm.

The polymer filler 130 provided to surround the plurality of piezoelectric sensors 110 may prevent vibrations of the plurality of respective piezoelectric sensors 110 from affecting one another. An array structure including the plurality of piezoelectric sensors 110 is manufactured by densely arranging the plurality of piezoelectric sensors 110, each having the pillar shape and forming the polymer filler 130 to surround the piezoelectric sensors 110. Therefore, as a larger number of piezoelectric sensors 110 are arranged within the same area, difficulty in a manufacturing process may be increased, thereby causing degradation in yield, or the like. However, since the fingerprint may be accurately detected by measuring a difference in acoustic impedance generated in valleys and ridges of the fingerprint by the ultrasonic signals discharged from the respective piezoelectric sensors 110, a possible large number of the piezoelectric sensors 110 need to be arranged within the same area so as to accurately detect the fingerprint.

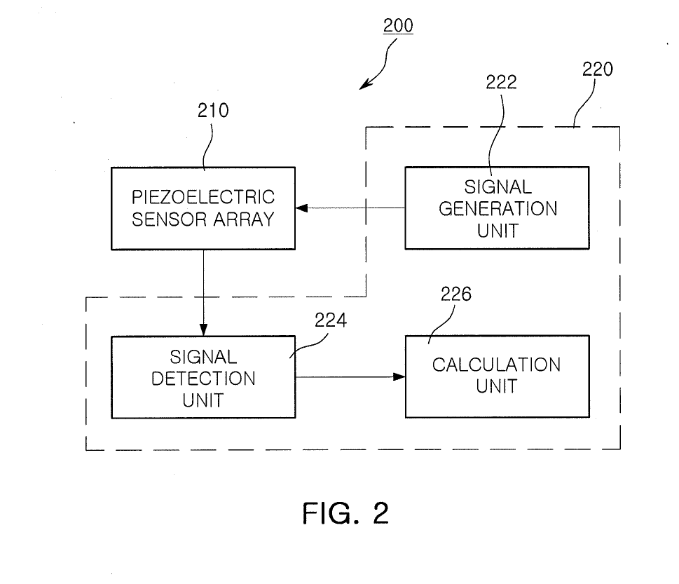

FIG. 2 is a block view schematically illustrating a fingerprint detection sensor according to another embodiment of the present invention.

Referring to FIG. 2, a fingerprint detection sensor 200 according to another embodiment of the present invention may include a piezoelectric sensor array 210 including the plurality of piezoelectric sensors 110 and the polymer filler 130 and a control unit 220. The control unit 220 may include a signal generation unit 220, a signal detection unit 224, a calculation unit 226, or the like.

The piezoelectric sensor array 210 may include the plurality of piezoelectric sensors 110 that are densely arranged in a matrix form and the polymer filler 130 that is provided to surround the plurality of piezoelectric sensors 110 to isolate the vibrations between the respective piezoelectric sensors 110, as shown in FIG. 1. Each of the piezoelectric sensors 110 may include a pillar made of a material facilitating vibrations and electrodes disposed on the top and bottom surfaces of the pillar and made of a conductive material. As described above, the pillar may be made of a material such as PZT and the electrodes may be made of a metal (Cu, Ag, Ni, Mo, an alloy thereof, or the like) having excellent conductivity.

The signal generation unit 222 may be electrically connected with the electrodes of the piezoelectric sensors 110 included in the piezoelectric sensor array 210 and apply alternating current (AC) voltage having a predetermined frequency to the respective electrodes. The ultrasonic signals having a predetermined resonance frequency (ex>10 MHz) are discharged to the outside while the pillars of the piezoelectric sensors 110 are vertically vibrated by the AC voltage applied to the electrodes.

A predetermined protective layer may be additionally disposed on the piezoelectric sensor array 210 and a specific object may contact a surface of the protective layer. When the object contacting the surface of the protective layer is a human finger including a fingerprint, reflection patterns of the ultrasonic signals discharged by the piezoelectric sensor 110 may be differently determined according to fine valleys and ridges of the fingerprint.

Provided that no object contacts a contact surface such as the surface of the protective layer, most ultrasonic signals discharged from the piezoelectric sensors 110 are reflected and returned without passing through the contact surface due to a difference in a medium between the contact surface and air. Conversely, when a specific object including the fingerprint contacts the contact surface, a certain amount of the ultrasonic signals discharged from the piezoelectric sensors 110 directly contacting the ridges of the fingerprint may pass through an interface between the contact surface and the fingerprint and the remainder of the generated ultrasonic signals may be reflected and returned. The intensity of the reflected and returned ultrasonic signals may be determined according to acoustic impedance of each material. Consequently, the signal detection unit 224 may measure a difference in acoustic impedance generated by the ultrasonic signals in the valleys and the ridges of the fingerprint through the respective piezoelectric sensors 110, to determine whether the corresponding piezoelectric sensors 110 are sensors contacting the ridges of the fingerprint.

The calculation unit 226 may analyze the signals detected by the signal detection unit 224 to calculate fingerprint patterns. As described above, the piezoelectric sensors 110, of which reflected signals have a low intensity, may be the piezoelectric sensors 110 contacting the ridges of the fingerprint, while the piezoelectric sensors 110, of which reflected signals have a high intensity, which ideally have an intensity almost equal to the intensity of output ultrasonic signals, may be the piezoelectric sensors 110 corresponding to the valleys of the fingerprint. Therefore, the fingerprint patterns may be calculated from the difference in acoustic impedance detected by the respective piezoelectric sensor 110.

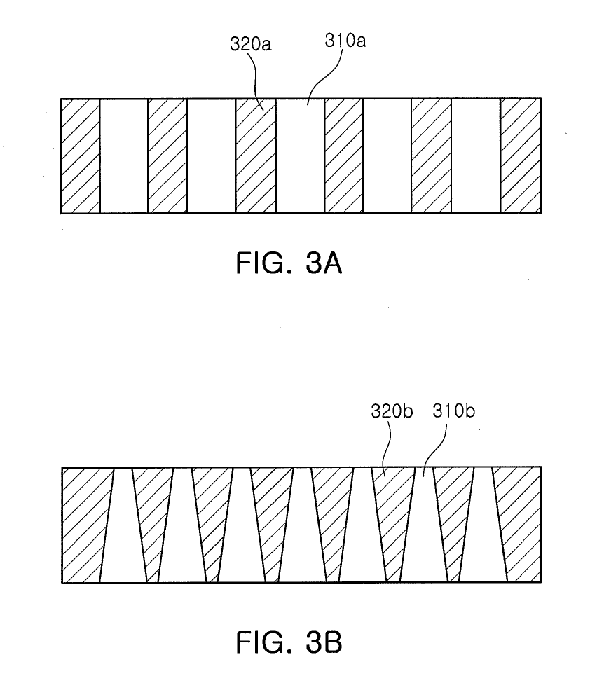

FIGS. 3A and 3B are cross-sectional views, each illustrating a plurality of piezoelectric sensors included in the fingerprint detection sensor according to another embodiment of the present invention. FIGS. 3A and 3B are views, each illustrating a cross section of the piezoelectric sensor array 210 included in the fingerprint detection sensor 200.

Referring first to FIG. 3A, a plurality of piezoelectric sensors 310a, each having a pillar shape and a polymer filler 320a are alternately arranged. As described above, each of the plurality of piezoelectric sensors 310a may include a pillar made of a vibrational material and electrodes disposed on the top and bottom surfaces of the pillar and having conductivity. The polymer filler 320a may be provided to surround the piezoelectric sensors 310a and isolate the vibrations between the respective piezoelectric sensors 310a. Each piezoelectric sensor 310a shown in FIG. 3A may have a cylindrical or a polygonal pillar in which the electrodes disposed on the top and bottom surfaces thereof have the same area.

Resolution in the fingerprint detection sensor may be defined by the number of piezoelectric sensors 310a included in the piezoelectric sensor array per unit area. Generally, in order to detect a fingerprint, a resolution of 500 dots per inch (DPI) may be needed, but in order to accurately detect the fingerprint of a child or woman in which the intervals between the valleys and ridges of the fingerprint may be narrow, a resolution higher than 500 DPI, preferably, a resolution of 700 DPI or more may be required.

In order to obtain the resolution higher than 500 DPI, there may be a need to densely arrange the piezoelectric sensor 310a by reducing areas of the top and bottom surfaces of the respective piezoelectric sensors 310a. However, as the piezoelectric sensors 310a are densely arranged, difficulty in a manufacturing process may be increased. In particular, during a process of arranging the piezoelectric sensors 310a and then, disposing the polymer filler 320a to surround the piezoelectric sensors 310a, a possibility to cause defects may be high, thereby generally leading to degradation in yield.

FIG. 3B shows a scheme according to the embodiment of the present invention for solving the above-mentioned problems. FIG. 3B may be similar to the piezoelectric sensor array of FIG. 3A in that a plurality of piezoelectric sensors 310b and a polymer filler 320b are alternately arranged. However, FIG. 33 is different from FIG. 3A, in that a cross section of each piezoelectric sensor 310b has a trapezoidal shape.

That is, the areas of top and bottom surfaces of each piezoelectric sensor 310b facing each other in a height direction are different from each other in FIG. 3B. When the top surface is defined by a first surface and the bottom surface is defined by a second surface, the area of the first surface of the piezoelectric sensor 310b may be smaller than that of the second surface thereof. The first surface may be disposed to be closer to a contact surface, with which the fingerprint is in contact, as compared with the second surface. Therefore, overall resolution in the fingerprint detection sensor may be determined according to the number of first surfaces disposed in the piezoelectric sensor array, per unit area.

That is, comparing FIG. 3A with FIG. 3B, FIG. 3A shows that a total of five piezoelectric sensors 310a are arranged while FIG. 3B shows that a total of seven piezoelectric sensors 310b are arranged, in the same width of the fingerprint sensor array, such that the overall resolution can be increased. In addition, since the area of the first surface is smaller than that of the second surface, when an injection of the polymer filler 310b is performed in a direction from the first surface toward the second surface, yield substantially the same level as that of the case shown in FIG. 3A can be obtained.

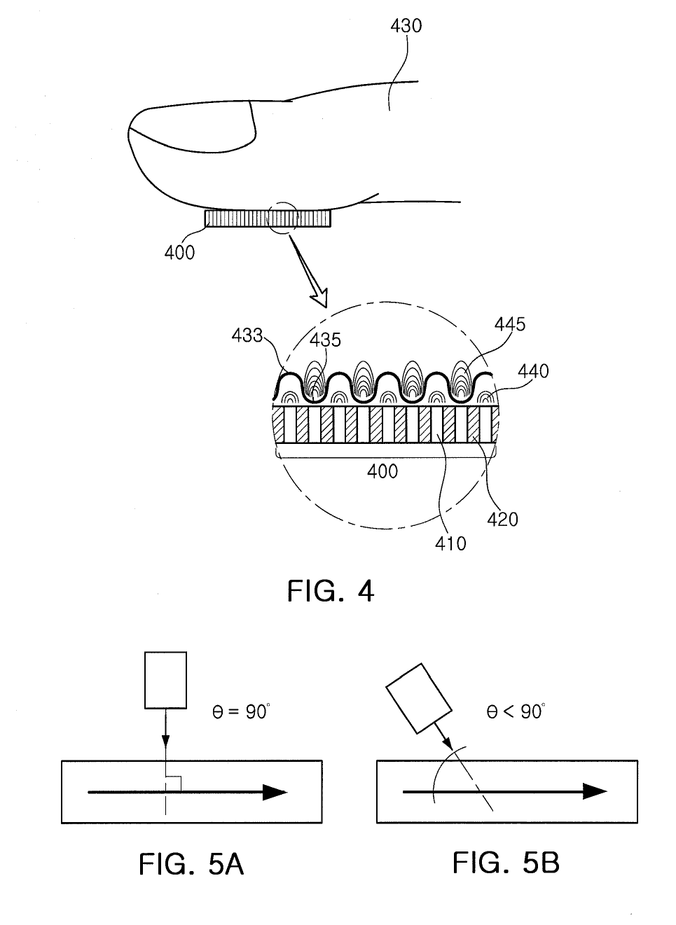

FIGS. 4 to 5 are views, each for explaining an operation principle of a fingerprint detection sensor according to another embodiment of the present invention.

Referring to FIG. 4, an object such as a finger 430, or the like, contacts on a fingerprint detection sensor 400. In a circular portion showing a partially enlarged cross-sectional view of the fingerprint detection sensor 400, the fingerprint detection sensor 400 may be formed by alternately arranging piezoelectric sensors 410 and a polymer filler 420, and ultrasonic signals having a predetermined frequency may be discharged to the finger 430 through first surfaces of the piezoelectric sensors 410.

Provided that the finger 430 is in non-contact with the fingerprint detection sensor 400, most ultrasonic signals discharged from the piezoelectric sensors 410 do not pass through an interface between the piezoelectric sensors 410 and air and may be returned into the piezoelectric sensors 410, due to a difference in acoustic impedance between the piezoelectric sensors 410 discharging the ultrasonic signals and air. On the other hand, when the finger 430 is in contact with the fingerprint detection sensor 400, a certain amount of the ultrasonic signals discharged from the piezoelectric sensors 410 may penetrate an interface between a skin of the finger 430 and the piezoelectric sensors 410 to be introduced into the finger 430. Therefore, the intensity of the returned and reflected signals becomes low, thereby enabling fingerprint patterns to be detected.

It may be difficult to distinguish the detected fingerprint patterns with the naked eye. However, the fingerprint of the finger 430 has patterns in which a large number of valleys 433 and ridges 435 are repeated and have differences in height. Therefore, as shown in the enlarged cross-sectional view of FIG. 4, the piezoelectric sensors 410 do not directly contact the skin in the valleys 433 of the fingerprint, the piezoelectric sensors 410 only directly contact the skin of the ridges 435 of the fingerprints.

As a result, an extremely small amount of ultrasonic signals 440 discharged from the piezoelectric sensors 410 corresponding to the valleys 433 of the fingerprint may be discharged to the outside and most of the ultrasonic signals 440 may be reflected into the piezoelectric sensors 410. A considerable amount of ultrasonic signals 445 discharged from the piezoelectric sensors 410 corresponding to the ridges 435 of the fingerprint may penetrate the interface between the finger 430 and the piezoelectric sensors 410 to be introduced into the finger 430, such that the intensity of reflected ultrasonic signals may be relatively largely reduced. Therefore, the fingerprint patterns of the finger 430 may be detected by measuring the intensity or reflection coefficient of the reflected signals generated through the reflection and return of the ultrasonic signals 440 and 445 caused by the difference in acoustic impedance according to the valleys 430 and the ridges 435 of the fingerprint, through the respective piezoelectric sensors 410.

FIG. 5 is a view showing a method of detecting a fluid flow by using an ultrasonic signal. The ultrasonic signals 445 discharged from the piezoelectric sensors 410 corresponding to the ridges 435 of the fingerprint of the finger 430 may penetrate the interface between the finger 430 and the piezoelectric sensors 410 to be introduced into the finger 430, such that blood (blood streams) flowing through a capillary vessel, or the like, within the finger 430 may be detected. However, as shown in FIGS. 5A and 5B, due to a use of the Doppler effect, when an incident angle at which the ultrasonic signals are incident on the capillary vessel is 90°, the blood streams may not be detected and when the incident angle is smaller than 90°, the blood streams may be detected by using the Doppler effect.

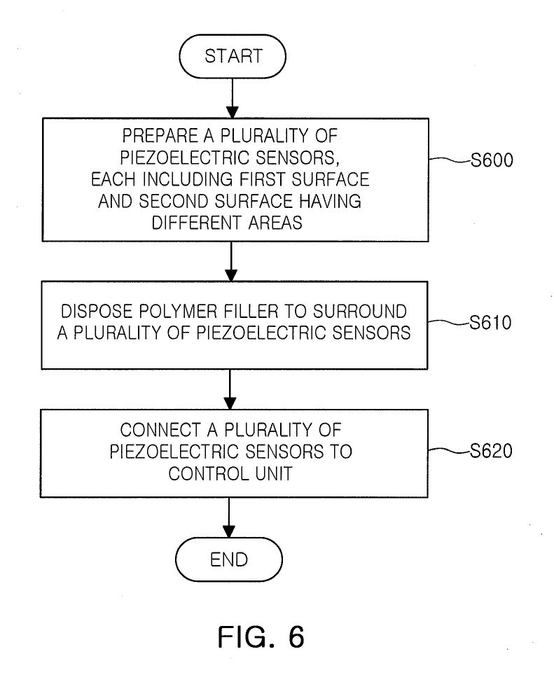

FIG. 6 is a flow chart for explaining a method of manufacturing a fingerprint detection sensor according to an embodiment of the present invention.

Referring to FIG. 6, in the method of manufacturing a fingerprint detection sensor according to the embodiment of the present invention, first, the plurality of piezoelectric sensors 110, each including the first surface and the second surface having different areas, may be prepared (S600). In this case, the first surface and the second having different areas may face each other in the height direction of the piezoelectric sensors 110. That is, provided that each piezoelectric sensor 110 has a pillar shape, the top and bottom surfaces of the piezoelectric sensor 110 each correspond to the first surface and the second surface.

As shown in FIG. 3B, the area of the first surface may be smaller than the area of the second surface such that the cross section of the piezoelectric sensor 310b has a trapezoidal shape. Provided that the ultrasonic signals are discharged through the first surface and the first surface is disposed to be close to a finger contact surface (a surface contacted by the finger), the resolution in the fingerprint detection sensor may be determined according to the number of first surfaces included in the piezoelectric sensor array per unit area. Therefore, the area of the first surface close to the finger contact surface may be smaller than that of the second surface, such that overall resolution in the fingerprint detection sensor can be increased without increasing the difficulty in the manufacturing process.

The polymer filler 130 may be disposed to surround the plurality of piezoelectric sensors 110 (S610). When the number of piezoelectric sensors 110 is increased in order to increase the resolution in the fingerprint detection sensor 100, unlike the embodiment of the present invention, the intervals between the piezoelectric sensors 110 become narrow to thereby cause defects in the injection of the polymer filler 130.

As in the embodiment of the present invention, when the area of the first surface close to the finger contact surface is small, there is no difference in that the number of piezoelectric sensors 110 is increased. However, a space into which the polymer filler 130 is injected may be sufficiently secured, such that a phenomenon in which yield in the injection of the polymer filler 130 is lowered may be prevented. As shown in FIG. 3B, since the first surface of the piezoelectric sensor 310b has a small area and accordingly, the space into which the polymer filler 320b is injected may be sufficiently secured, a process may be facilitated as compared with the case of FIG. 3A in which the number of piezoelectric sensors 310a, each having the same area of the first surface and the second surface, is increased.

The plurality of piezoelectric sensors 110 are connected to the control unit 130 (S620). The control unit 130 may discharge the ultrasonic signals through the plurality of piezoelectric sensors 110 and detecting the fingerprint patterns by detecting the reflected signals generated through the reflection and return of the discharged ultrasonic signals due to the difference in acoustic impedance.

As set forth above, according to the embodiments of the present invention, the fingerprint detection sensor having a high resolution without an increase in the overall size thereof can be provided. Therefore, according to the embodiments of the present invention, the fingerprint detection sensor having a high accuracy capable of accurately detecting the fingerprint in which intervals between valleys and ridges are narrow, in particular, the fingerprint of a child and women can be provided.

While the present invention has been shown and described in connection with the embodiments, it will be apparent to those skilled in the art that modifications and variations can be made without departing from the spirit and scope of the invention as defined by the appended claims.

What is claimed is:

1. A fingerprint detection sensor, comprising:
a plurality of piezoelectric sensors arranged in an array on a two-dimensional plane and having a predetermined height;
a filler provided to surround the plurality of piezoelectric sensors and isolating vibrations between the plurality of piezoelectric sensors; and
a control unit discharging predetermined output signals through the piezoelectric sensors to detect information of an object in contact with, or close to, the plurality of piezoelectric sensors,
wherein the plurality of piezoelectric sensors include first surfaces and second surfaces disposed on both ends thereof in a height direction and areas of the first surfaces and the second surfaces are different from each other.

2. The fingerprint detection sensor of claim 1, wherein the first surfaces of the plurality of piezoelectric sensors have an area smaller than that of the second surfaces and the first surfaces are disposed to be closer to the object, as compared with the second surfaces.

3. The fingerprint detection sensor of claim 2, wherein the plurality of piezoelectric sensors are arranged such that the first surfaces have a resolution of 500 dots per inch (DPI) or more on the two-dimensional plane.

4. The fingerprint detection sensor of claim 1, wherein the control unit discharges ultrasonic output signals having a predetermined frequency through the plurality of piezoelectric sensors and detects fingerprint information of the object by measuring a difference in acoustic impedance generated in valleys and ridges of the object by the output signals.

5. The fingerprint detection sensor of claim 4, wherein the control unit detects the fingerprint information of the object based on the difference between first acoustic impedance corresponding to the valleys of the object and second acoustic impedance corresponding to the ridges of the object.

6. The fingerprint detection sensor of claim 1, wherein the control unit detects fingerprint patterns of the object.

7. The fingerprint detection sensor of claim 1, further comprising a polymer filler disposed to surround the plurality of piezoelectric sensors.

8. The fingerprint detection sensor of claim 1, further comprising a protective layer provided on the plurality of piezoelectric sensors.

9. A method of manufacturing a fingerprint detection sensor determining information of a contacting or approaching object, the method comprising:
preparing a plurality of piezoelectric sensors, each including a first surface and a second surface facing each other in a height direction thereof and having different areas;
disposing a polymer filler to surround the plurality of piezoelectric sensors; and
connecting a control unit discharging predetermined output signals through the plurality of piezoelectric sensors to the plurality of piezoelectric sensors.

10. The method of claim 9, wherein the area of the first surface is smaller than that of the second surface.

11. The method of claim 10, wherein the preparing of the plurality of piezoelectric sensors is performed such that the first surface is positioned to be closer to the contacting or approaching object, as compared with the second surface.

12. The method of claim 9, wherein in the connecting of the control unit, the control unit determining information of the object by comparing a frequency of output signals discharged through the plurality of piezoelectric sensors with a frequency of reflection signals reflected from the object, is connected to the plurality of piezoelectric sensors.

13. The method of claim 9, wherein the preparing of the plurality of piezoelectric sensors is performed such that the plurality of piezoelectric sensors have a resolution of 500 DPI or more on a two-dimensional plane, with which the object is in contact or approaching.
